(19) United States
(12) Patent Application Publication
(10) Pub. No.: US 2022/0223345 A1
(43) Pub. Date: Jul. 14, 2022

(54) GAS CAPACITOR FOR SEMICONDUCTOR TOOL

(71) Applicant: FABWORX SOLUTIONS, INC., Austin, TX (US)

(72) Inventors: TOM RANDALL, Archer City, TX (US); MICHAEL DAILEY, Austin, TX (US); THOMAS E. WALTON, Manor, TX (US)

(21) Appl. No.: 17/610,155

(22) PCT Filed: May 11, 2020
(86) PCT No.: PCT/US20/32396

§ 371 Date: Nov. 10, 2021

Related U.S. Application Data
(60) Provisional application No. 62/846,360, filed on May 10, 2019.

(51) Int. Cl. H01G 4/02; H01G 4/224

(52) U.S. Cl. CPC H01G 4/02; C23C 16/455; H01G 4/224

(57) ABSTRACT

A system is provided which includes a gas supply; a fluidic circuit which includes first and second sub-circuits, wherein said first sub-circuit includes a first one-way valve, and wherein said second sub-circuit includes a second one-way valve and a gas capacitor disposed downstream of said second one-way valve; and a pneumatically operated semiconductor tool in fluidic communication with said gas supply by way of said fluidic circuit.

### CROSS-REFERENCE TO RELATED APPLICATIONS

The present application is a national stage filing of PCT/US20/32396, filed on May 11, 2020, which has the same title and the same inventors, and which is incorporated herein by reference in its entirety; which claims priority to U.S. provisional patent application No. 62/846,360, which was filed on May 10, 2019, which has the same title and inventors, and which is incorporated herein by reference in its entirety.

### TECHNICAL FIELD OF THE INVENTION

The present invention pertains generally to tools used for semiconductor fabrication, and more particularly, to a gas capacitor for such tools.

### BACKGROUND OF THE INVENTION

In a typical semiconductor manufacturing process, a single wafer is exposed to a number of sequential processing steps including, but not limited to, chemical vapor deposition (CVD), physical vapor deposition (PVD), etching, planarization, and ion implantation. These processing steps are typically performed by robots, due in part to the ability of robots to perform repetitive tasks quickly and accurately and to work in environments that are dangerous to humans.

Many modern semiconductor processing systems are centered around robotic cluster tools that integrate a number of process chambers. This arrangement allows multiple sequential processing steps to be performed on the wafer within a highly controlled processing environment, and thus minimizes exposure of the wafer to external contaminants. The combination of chambers in a cluster tool, as well as the operating conditions and parameters under which those chambers are utilized, may be selected to fabricate specific structures using a specific process recipe and process flow. Some commonly used process chambers include degas chambers, substrate pre-conditioning chambers, cool down chambers, transfer chambers, chemical vapor deposition chambers, physical vapor deposition chambers and etch chambers.

FIG. 1 is a schematic diagram of the integrated cluster tool 10 of U.S. Pat. No. 6,222,337 (Kroeker et al.). Wafers are introduced into, and withdrawn from, the cluster tool 10 through a cassette loadlock 12. A robot 14 having an end effector 17 is located within the cluster tool 10 to transfer wafers from one processing chamber 20 to another. These processing chambers may include a cassette load lock 12, a degas wafer orientation chamber 20, a pre-clean chamber 24, a PVD TiN chamber 22 and a cool-down chamber 26. The end effector 17 is illustrated in the retracted position in which it can rotate freely within the chamber 18.

A second robot 28 is located in transfer chamber 30 and is adapted to transfer wafers between various chambers, such as a cool-down chamber 26, a pre-clean chamber 24, a CVD Al chamber (not shown) and a PVD AlCu processing chamber (not shown). The specific configuration of chambers illustrated in FIG. 1 is designed to provide an integrated processing system capable of both CVD and PVD processes in a single cluster tool. A microprocessor controller 29 is provided to control the fabricating process sequence, conditions within the cluster tool, and the operation of the robots 14, 28.

FIG. 2 is a schematic view of the magnetically coupled robot of FIG. 1 shown in both the retracted and extended positions. The robot 14 (see FIG. 1) includes a first strut 81 which is rigidly attached to a first magnet clamp 80, and a second strut 82 which is rigidly attached to a second magnet clamp 80′. A third strut 83 is attached by a pivot 84 to strut 81 and by a pivot 85 to end effector 86. A fourth strut 87 is attached by a pivot 88 to strut 82 and by a pivot 89 to end effector 86. The structure of struts 81-83, 87 and pivots 84, 85, 88, and 89 form a “frog leg” type connection of end effector 86 to magnet clamps 80,80′.

When magnet clamps 80, 80′ rotate in the same direction with the same angular velocity, then the robot also rotates about axis x in this same direction with the same velocity. When magnet clamps 80, 80′ rotate in opposite directions with the same absolute angular velocity, then there is no rotation of assembly 14, but instead there is linear radial movement of end effector 86 to a position illustrated by dashed elements 81′-89′.

Referring still to FIG. 2, a wafer 35 is shown being loaded on end effector 86 to illustrate that the end effector can be extended through a wafer transfer slot 90 in a wall 91 of a chamber 32 to transfer such a wafer into or out of the chamber 32. The wafer transfer slot 90 commonly takes the form of a pneumatically actuated rectangular transfer valve or slit valve, an example of which is shown in FIG. 3.

Still referring to FIG. 2, the mode in which both magnet clamps 80, 80′ rotate in the same direction at the same speed can be used to rotate the robot from a position suitable for wafer exchange with one of the adjacent chambers 12, 20, 22, 24, 26 (see FIG. 1), to a position suitable for wafer exchange with another of these chambers. The mode in which both magnet clamps 80, 80′ rotate with the same speed in opposite directions is then used to extend the end effector into one of these chambers and then extract it from that chamber. Some other combination of clamp rotation may be used to extend or retract the end effector as the robot is being rotated about axis x.

There is considerable pressure in the semiconductor industry to increase throughput at semiconductor fabs. Consequently, cluster tools of the type depicted in FIGS. 1-2 have been required to operate at increasingly higher speeds to keep up with increasing throughput requirements.

During their operation, cluster tools are frequently required to pneumatically isolate a particular processing chamber from the rest of the tool. This is typically accomplished through the use of pneumatically actuated slit valves. An example of one embodiment of a slit valve 101 is depicted in FIG. 3 (the slit valve 101 is seated in the wafer transfer slot 90 of FIG. 2). The particular slit valve 101 depicted in FIG. 3 is a V74 Series slit valve which is commercially available from the Kurt J. Lesker Company (Jefferson Hills, Pa.). This slit valve 101 comprises a frame 103 having a window 105 disposed therein, and is further equipped with a pneumatic inlet 107 that is fluidically coupled to a gas supply line (not shown). Other commonly utilized slit valves include those which are available from SMC Corporation (Tokyo, Japan) such as, for example, the pneumatic slit valve sold under the product designation SMC US13394.

Slit valves are commonly used as partition valves between the load lock chamber and the transfer chamber, or between the transfer chamber and the process chamber, in semiconductor manufacturing equipment. The gas supply line provides a working gas (typically clean dry air (CDA)) that serves to open and close the slit valves.

### SUMMARY OF THE INVENTION

In one aspect, a combination of a gas capacitor and a semiconductor tool is provided. The semiconductor tool comprises (a) a gas supply line which supplies gas from a remote gas source and which is equipped with a first one-way valve, (b) a central chamber, and (c) a plurality of process chambers, wherein each of said plurality of process chamber is equipped with a pneumatically actuated valve which is in fluidic communication with the gas supply line and which transforms the process chamber from a first state in which the process chamber is in fluidic communication with said central chamber, to a second state in which the process chamber is fluidically isolated from said central chamber. The gas capacitor comprises a pressurized gas reservoir which is disposed downstream from said one-way valve, and which is in fluidic communication with said plurality of process chambers.

In another aspect, a system is provided which comprises (a) a gas supply; (b) a fluidic circuit which includes first and second sub-circuits, wherein said first sub-circuit includes a first one-way valve, and wherein said second sub-circuit includes a second one-way valve and a gas capacitor disposed downstream of said second one-way valve; and (c) a pneumatically operated semiconductor tool in fluidic communication with said gas supply by way of said fluidic circuit.

### BRIEF DESCRIPTION OF THE DRAWINGS

For a more complete understanding of the present invention and the advantages thereof, reference is now made to the following description taken in conjunction with the accompanying drawings in which like reference numerals indicate like features.

FIG. 1 is an illustration of a prior art cluster tool equipped with a robotic wafer handling system.

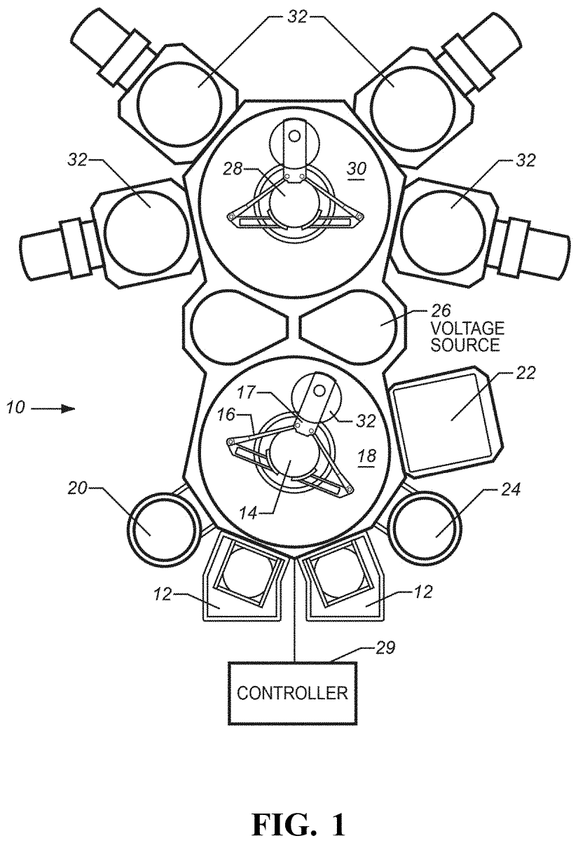

FIG. 2 is an illustration of the arm assembly of the robot depicted in FIG. 1, and illustrates the retracted and extended positions of the arm assembly.

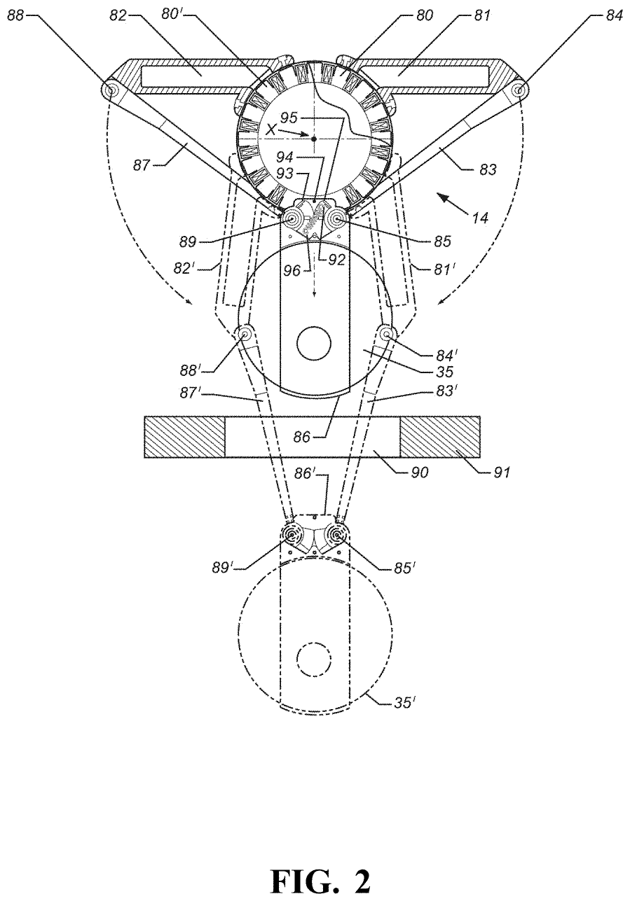

FIG. 3 is a front view of a prior art slit valve.

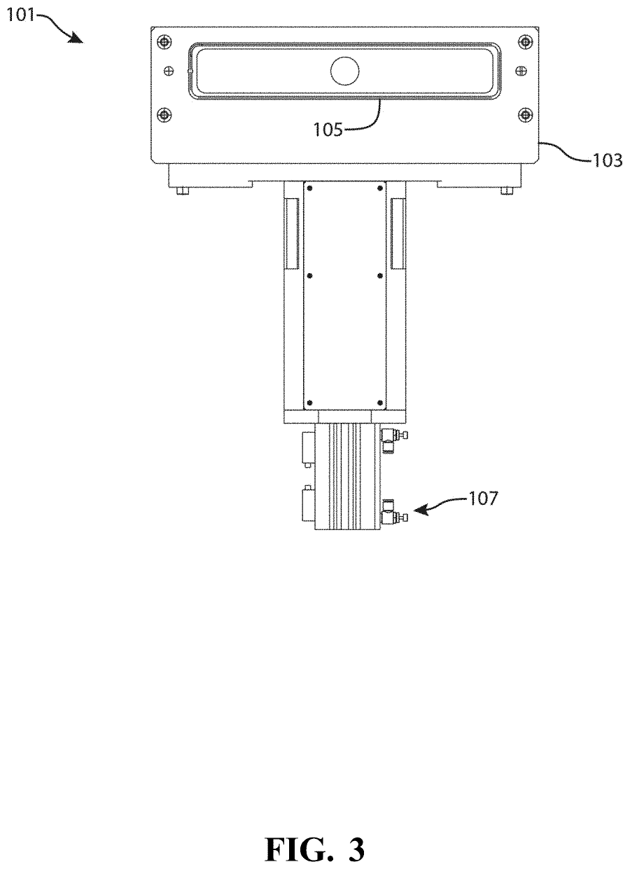

FIG. 4 is a side view of the slit valve of FIG. 3.

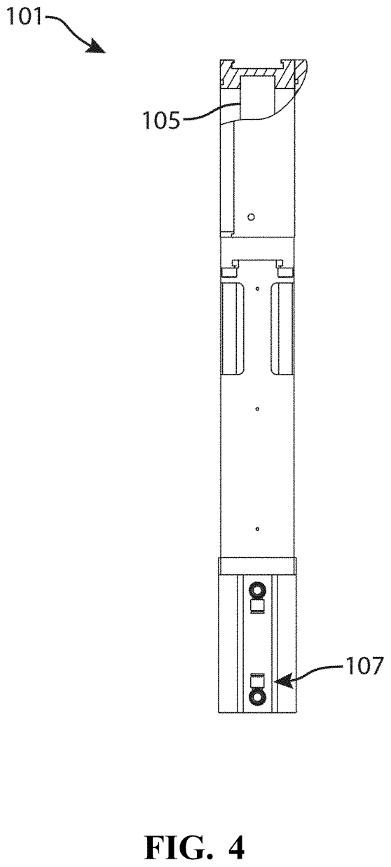

FIG. 5 is an illustration of a semiconductor fab layout featuring a remote gas supply and a plurality of cluster tools.

FIG. 6 is a schematic illustration of a system which includes a gas supply and a semiconductor tool and which is equipped with a gas capacitor in accordance with the teachings herein.

FIG. 7 is a detailed illustration of the gas capacitor of FIG. 6.

### DETAILED DESCRIPTION OF THE INVENTION

The trend toward operating cluster tools at higher speeds has resulted in more slit valve actuations occurring simultaneously. Cluster tools are typically equipped with a long length of piping that supplies the working gas for the pneumatic system. Since this piping has a finite flow capacity, the simultaneous operation of an increasing number of slit valves (as necessary to accommodate higher throughput speeds) places increasing demands on the pneumatic system. This frequently results in dramatic fluctuations in pneumatic pressure at the cluster tool, which can lead to tool alarms, chamber leaks and slow actuations of the slit valves. In order to reduce such pressure fluctuations and to accommodate the necessary flow requirements, the clean dry air (CDA) pressure at the tool is frequently increased beyond the suggested limitations of the slit valves.

It has been found that, as a result of their frequent exposure to CDA pressures that exceed their design capabilities, the slit valves in a cluster tool suffer frequently exhibit premature wear. This is often manifested as a breakdown of the O-ring material in the valve, which may lead to particle generation.

On the other hand, if CDA pressures in the tool drop below the required level, the slit valves may not fully actuate, which may leave them in an unknown open/closed state. If these faults occur during wafer transfer, the robot and wafer may be left in an unknown position. Similarly, if the CDA supply is depleted, tool technicians may have no options for wafer recovery, and may be forced to wait for the CDA supply to recover. Either of these scenarios may lead to wafer scrap that may have been averted if the tool technicians had been able to quickly remove the wafers from the tool.

It has now been found that some or all of the foregoing issues may be addressed with the systems and methodologies disclosed herein. In a preferred embodiment of such a system, a gas capacitor, preferably in the form of a pressurized vessel, is added locally to the cluster tool at a location near (and upstream from) the slit valves. The gas capacitor, which is in fluidic communication with the slit valves, provides an additional local reservoir of working gas (preferably CDA) local to the tool. The availability of this additional reservoir local to the tool increases the effective volume of CDA available to the tool, while also decreasing the effective length of pipe supplying the CDA. This arrangement significantly reduces or eliminates the pressure fluctuations which otherwise arise from the simultaneous operation of an increasing number of slit valves. Consequently, the operating pressure may be set at lower values (e.g., those recommended by the tool manufacturer), even if the remote supply of CDA is servicing multiple tools and/or a large number of slit valves simultaneously.

Moreover, the gas capacitor may be configured to allow the tool to cease operation if the facility CDA pressure drops sufficiently (as is currently the case), but to maintain a reservoir of CDA of sufficient volume and pressure to allow for manual operation of the slit valves in the tool. This provides a means by which in-process wafers may be recovered, thus avoiding some of the cost and waste attendant to CDA disruptions.

In some embodiments, the auxiliary gas supply may be configured to be removable from (or fluidically or pneumatically isolated from) the tool. This may be accomplished, for example, through the provision of a bypass line. This feature allows the auxiliary gas supply to be removed for maintenance or replacement without disrupting the operation of the associated tool, and without introducing moisture or other contaminants into the gas circuit.

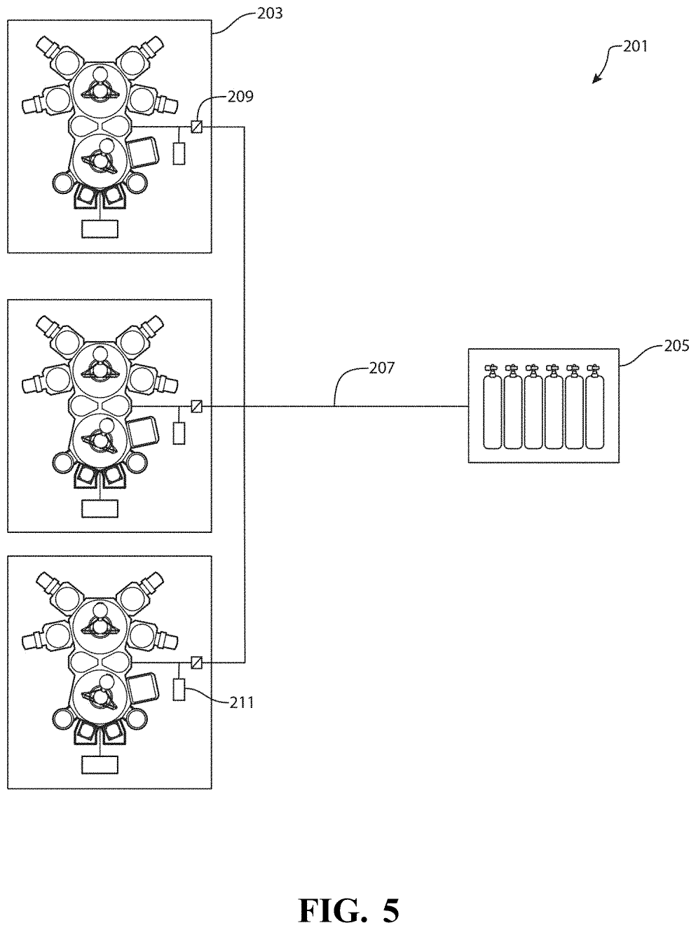

FIG. 5 depicts a particular, non-limiting embodiment of a semiconductor fab layout. As seen therein, the layout 201 comprises a plurality of cluster tools 203 that are in fluidic communication with a remote gas supply 205 via a gas supply line 207. Each of the cluster tools 203 is equipped with a one-way check valve 209 which isolates the tool from the gas supply line 207 in the event of a sufficiently large pressure drop. The check valve 209 preferably serves as a pneumatic lock-up valve which functions to shut off the signal pressure line of pneumatic actuators when the pressure in the gas supply line falls below a predetermined threshold value. This typically causes the pneumatically activated actuators in the tool (including those in the slit valves) to remain in their last position.

The check valve 209 is characterized by a cracking pressure P_{crack}. At pressures above the cracking pressure, the valve assumes an open state in which fluidic flow between the remote gas supply and the tool occurs. Similarly, at pressures below the cracking pressure, the valve assumes a closed state in which no fluidic flow between the gas reservoir and the gas supply line occurs. The gas supply line will typically experience operating pressure fluctuations while the semiconductor tool is in operation. These operating pressure fluctuations are characterized by a maximum pressure Pₘₐₓ and a minimum pressure Pₘᵢₙ. Preferably, the check valve is designed such that 0<P_{crack}<Pₘᵢₙ. Typically, Pₘᵢₙ>30 psi, and preferably, Pₘᵢₙ≥60 psi. Typically, Pₘₐₓ<100 psi, and preferably, Pₘₐₓ≤90 psi. Moreover, typically, 10 psi<P_{crack}<60 psi, and preferably, 20 psi<P_{crack}<50 psi.

Each cluster tool 203 is also equipped with a gas capacitor 211 of the type disclosed herein, which is preferably located downstream of the check valve 209. As described below, the gas capacitor 211 serves as a local supply of gas, in contrast to the remote gas supply 205 from the facility. It will be appreciated that, while the check valve 209 is depicted as a separate component from the gas capacitor 211 in FIG. 5, in some embodiments, the check valve will actually be a component of the gas capacitor.

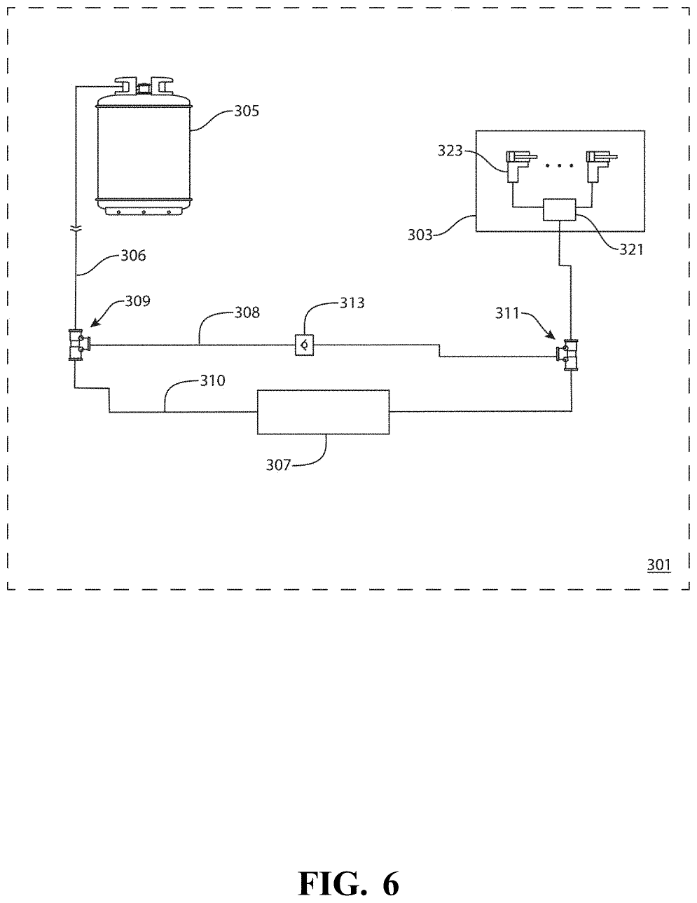

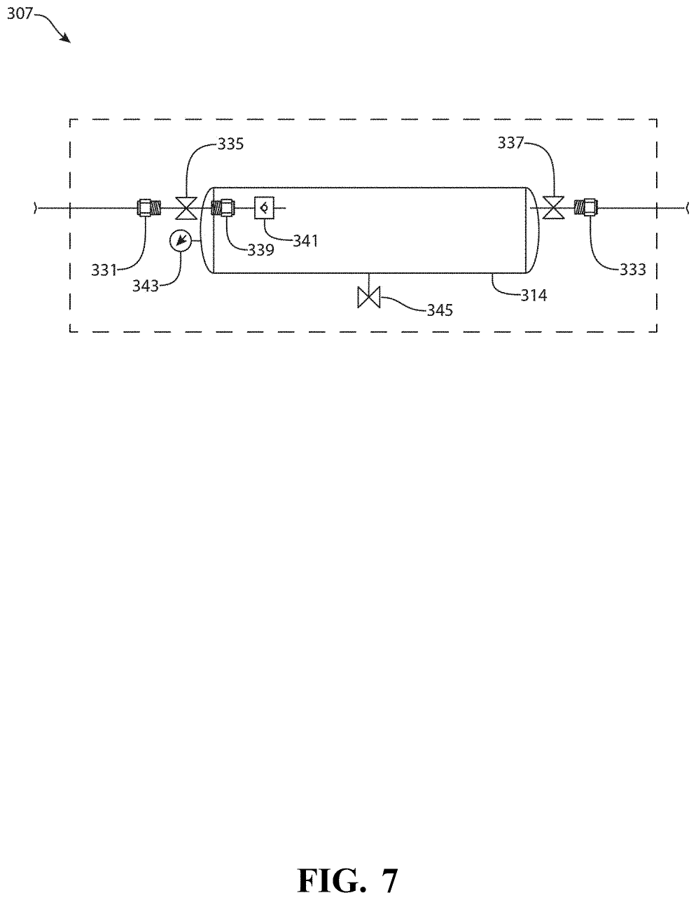

FIGS. 6-7 depict a first particular, non-limiting embodiment of a system 301 incorporating a gas capacitor 307 in accordance with the teachings herein. As seen therein, the system 301 comprises a pneumatically powered semiconductor tool 303 which is in fluidic communication with a facility gas supply 305 via a fluidic circuit 306 that includes first 308 and second 310 sub-circuits. The first 308 and second 310 sub-circuits are in fluidic communication with each other via first 309 and second 311 T-joints. The first sub-circuit 308 includes check valve 313, and the second sub-circuit includes gas capacitor 303. Check valve 313 maintains a one-way flow in the first sub-circuit 308 in the direction going from the first T-joint 309 to the second T-joint 311. The semiconductor tool 303 is equipped with a plurality of slit valves 323 that are in fluidic communication with fluidic circuit 306 via a manifold 321.

The gas capacitor 303 is depicted in greater detail in FIG. 7. As seen therein, the gas capacitor 307 comprises a gas reservoir 314 equipped with a pressure gauge 343. The gas reservoir 314 is preferably a gas cylinder, and more preferably, an aluminum gas cylinder. The use of aluminum in the construction of the gas reservoir 314 is preferred here because aluminum poses a lower contamination threat than other metals commonly used in the construction of gas cylinders. The pressure gauge 343 is preferably fitted with a filtered exhaust. The pressure gauge 343 is useful during initial installation and charging of the gas reservoir 314 to ensure that the initial pressure remains steady (i.e., there are no leaks present in the gas capacitor 307).

The gas capacitor 307 further comprises first 335 and second 337 manually operated isolation valves. The first isolation valve 335 is associated with fittings 331 and 339, and the second isolation valve 337 is associated with fitting 333. The first 335 and second 337 isolation valves are preferably disposed immediately upstream and immediately downstream, respectively, from the gas reservoir 314, and thus provide a means to readily remove the gas reservoir 314 from the pneumatic circuit 306 as, for example, for repair or maintenance. The gas capacitor 307 is further equipped with a check valve 341, which maintains a one-way flow in the direction going from the first isolation valve 335 to the second isolation valve 337.

In some embodiments, the gas capacitor 307 may include additional components. Thus, for example, in some embodiments, the gas capacitor 307 or the fluidic circuit 306 may include a gas dryer, which is preferably a modular adsorption dryer. The gas dryer serves to remove water vapor from the gas supply, thus preventing condensation, corrosion and the growth of microorganisms. In some embodiments, the gas dryer may be equipped with a suitable desiccant. One or more filters may also be provided in the gas capacitor 307 or the fluidic circuit 306 to remove impurities therefrom such as, for example, liquid water, water aerosols, oil, particulates, or microorganisms.

In normal use of the system 301, as pressure fluctuations are propagated through fluidic circuit 306, the check valve 313 remains open so long as the pressure in fluidic sub-circuit 308 upstream of the check valve 313 does not fall below Pₘᵢₙ. These pressure fluctuations are compensated for by the gas capacitor 307 as a result of the additional, localized reservoir of pressurized gas it provides via gas reservoir 314.

However, if the pressure in fluidic sub-circuit 308 upstream of the check valve 313 line falls below P_{crack}, the check valve 313 is activated (that is, moves from an open position in which fluidic flow through the check valve 313 is permitted, to a closed position in which fluidic flow through the check valve 313 is not permitted), and the gas supply to the tool 303 is cut off. Since the check valve 313 is a one-way valve, the portion of the first sub-circuit 318 upstream of the check valve 313 remains fluidically isolated from the tool 303, and hence, working gas pressure is maintained in the portion of the first sub-circuit 308 downstream of the check valve 313. Similarly, the one-way flow provided by check valve 341 (see FIG. 7) ensures that the portion of the second sub-circuit 310 upstream of the check valve 341 remains fluidically isolated from the tool 303, and hence, working gas pressure is maintained in the portion of the second sub-circuit 310 downstream of the check valve 313. Since check valves 313 and 341 provide a one-way flow of fluid, and since the gas reservoir 314 of the gas capacitor 307 is downstream from the check valve 341, the additional, localized reservoir of pressurized gas provided by gas reservoir 314 may be utilized to manually operate slit valves 323 or other pneumatically operated components of the tool 303. This allows for wafer recovery and temporary operation of the slit valves, even if the facility gas supply 305 remains offline.

Preferred embodiments of this invention are described herein, including the best mode known to the inventors for carrying out the invention. Variations of those preferred embodiments may become apparent to those of ordinary skill in the art upon reading the foregoing description. The inventors expect skilled artisans to employ such variations as appropriate, and the inventors intend for the invention to be practiced otherwise than as specifically described herein. Accordingly, this invention includes all modifications and equivalents of the subject matter recited in the claims appended hereto as permitted by applicable law. Moreover, any combination of the above-described elements in all possible variations thereof is encompassed by the invention unless otherwise indicated herein or otherwise clearly contradicted by context.

What is claimed is:

1. A gas capacitor in combination with a semiconductor tool, wherein said semiconductor tool comprises:
a gas supply line which supplies gas from a remote gas source and which is equipped with a first one-way valve,
a central chamber, and
a plurality of process chambers,
wherein each of said plurality of process chamber is equipped with a pneumatically actuated valve which is in fluidic communication with the gas supply line and which transforms the process chamber from a first state in which the process chamber is in fluidic communication with said central chamber, to a second state in which the process chamber is fluidically isolated from said central chamber; and
wherein said gas capacitor comprises:
a pressurized gas reservoir which is disposed downstream from said one-way valve, and which is in fluidic communication with said plurality of process chambers.

2. The apparatus of claim 1, wherein said gas reservoir is disposed in said semiconductor tool.

3. The apparatus of claim 1, wherein said gas reservoir is disposed proximal to said semiconductor tool.

4. The apparatus of claim 1, wherein said first one-way valve is characterized by a cracking pressure P_{crack}; wherein, at pressures above the cracking pressure, the first one-way valve assumes an open state in which fluidic flow between the gas reservoir and the gas supply line occurs; and wherein, at pressures below the cracking pressure, the first one-way valve assumes a closed state in which no fluidic flow between the gas reservoir and the gas supply line occurs.

5. The apparatus of claim 4, wherein the gas supply line experiences operating pressure fluctuations while the semiconductor tool is in operation, and wherein the operating pressure fluctuations are characterized by a maximum pressure Pₘₐₓ and a minimum pressure Pₘᵢₙ, and wherein 0<P_{crack}<Pₘᵢₙ.

6. The apparatus of claim 5, wherein Pₘᵢₙ>50 psi.

7. The apparatus of claim 5, wherein Pₘᵢₙ≥60 psi.

8. The apparatus of claim 5, wherein Pₘₐₓ<100 psi.

9. The apparatus of claim 5, wherein Pₘₐₓ≤90 psi.

10. The apparatus of claim 5, wherein 10 psi<P_{crack}<60 psi.

11. The apparatus of claim 5, wherein 20 psi<P_{crack}<50 psi.

12. A system, comprising:
a gas supply;
a fluidic circuit which includes first and second sub-circuits, wherein said first sub-circuit includes a first one-way valve, and wherein said second sub-circuit includes a second one-way valve and a gas capacitor disposed downstream of said second one-way valve; and
a pneumatically operated semiconductor tool in fluidic communication with said gas supply by way of said fluidic circuit.

13. The system of claim 12, wherein said first and second one-way valves impart a one-way flow of fluid between said gas supply and said semiconductor tool.

14. The system of claim 12, wherein said semiconductor tool includes a central chamber and a plurality of process chambers, and wherein each of said plurality of process chamber is equipped with a pneumatically actuated valve which is in fluidic communication with the fluidic circuit.

15. The system of claim 12, wherein each pneumatically actuated valve is transformable between a first state in which the process chamber associated with the pneumatically actuated valve is in fluidic communication with said central chamber, to a second state in which the process chamber associated with the pneumatically actuated valve is fluidically isolated from said central chamber.

16. The system of claim 12, wherein said gas capacitor includes a pressurized gas reservoir which is disposed downstream from said second one-way valve, and which is in fluidic communication with said plurality of process chambers.

17. The system of claim 12, wherein said first and second sub-circuits are in fluidic communication with each other.
